(19) United States
(12) Patent Application Publication
(10) Pub. No.: US 2019/0285696 A1
(43) Pub. Date: Sep. 19, 2019

(54) SEMICONDUCTOR DEVICE AND FAILURE DIAGNOSIS METHOD

(71) Applicants: Kabushiki Kaisha Toshiba, Tokyo (JP); Toshiba Electronic Devices & Storage Corporation, Tokyo (JP)

(72) Inventor: Tomoyuki Maekawa, Fujisawa Kanagawa (JP)

(21) Appl. No.: 16/127,650

(22) Filed: Sep. 11, 2018

(30) Foreign Application Priority Data
Mar. 15, 2018 (JP) 2018-048362

(51) Int. Cl. G01R 31/3187; G01R 31/3181; G01R 31/3185

(52) U.S. Cl. CPC G01R 31/3187; G01R 31/31813; G01R 31/318558; G01R 31/318566; G01R 31/318572

(57) ABSTRACT

According to one embodiment, there is provided a semiconductor device including a first block and a second block. The second block is adjacent to the first block. The first block includes a logic circuit, a built-in self test (BIST) circuit, an interface circuit, and a failure monitoring circuit. The built-in self test (BIST) circuit is connected to the logic circuit. The interface circuit is placed between the second block and the BIST circuit. The failure monitoring circuit is connected to the interface circuit.

### CROSS-REFERENCE TO RELATED APPLICATIONS

This application is based upon and claims the benefit of priority from Japanese Patent Application No. 2018-048362, filed on Mar. 15, 2018; the entire contents of which are incorporated herein by reference.

### FIELD

Embodiments described herein relate generally to a semiconductor device and a failure diagnosis method.

### BACKGROUND

In semiconductor devices in which a logic circuit and a built-in self test (BIST) circuit are incorporated, by inspecting the logic circuit using the BIST circuit, it can be determined whether the logic circuit is good or not. At this time, for the purpose of appropriately determining whether the logic circuit is good or not, it is desired to perform failure diagnosis in the semiconductor device appropriately.

### BRIEF DESCRIPTION OF THE DRAWINGS

FIG. 1 is a diagram illustrating the configuration of a semiconductor device according to an embodiment;

FIG. 2 is a diagram illustrating the configuration of a logic BIST block in the embodiment;

FIG. 3 is a time chart illustrating the operation of the semiconductor device according to the embodiment;

FIG. 4 is a diagram illustrating the configuration of an input interface circuit and a failure monitoring circuit in the embodiment;

FIG. 5 is a diagram illustrating the configuration of an output interface circuit and a failure monitoring circuit in the embodiment;

FIG. 6 is a diagram illustrating the configuration located between logic BIST blocks in the embodiment at the time of logic BIST diagnosis; and

FIG. 7 is a diagram illustrating the configuration of the output interface circuit and a failure monitoring circuit in the embodiment.

### DETAILED DESCRIPTION

In general, according to one embodiment, there is provided a semiconductor device including a first block and a second block. The second block is adjacent to the first block. The first block includes a logic circuit, a built-in self test (BIST) circuit, an interface circuit, and a failure monitoring circuit. The built-in self test (BIST) circuit is connected to the logic circuit. The interface circuit is placed between the second block and the BIST circuit. The failure monitoring circuit is connected to the interface circuit.

Exemplary embodiments of a semiconductor device will be explained below in detail with reference to the accompanying drawings. The present invention is not limited to the following embodiments.

### Embodiment

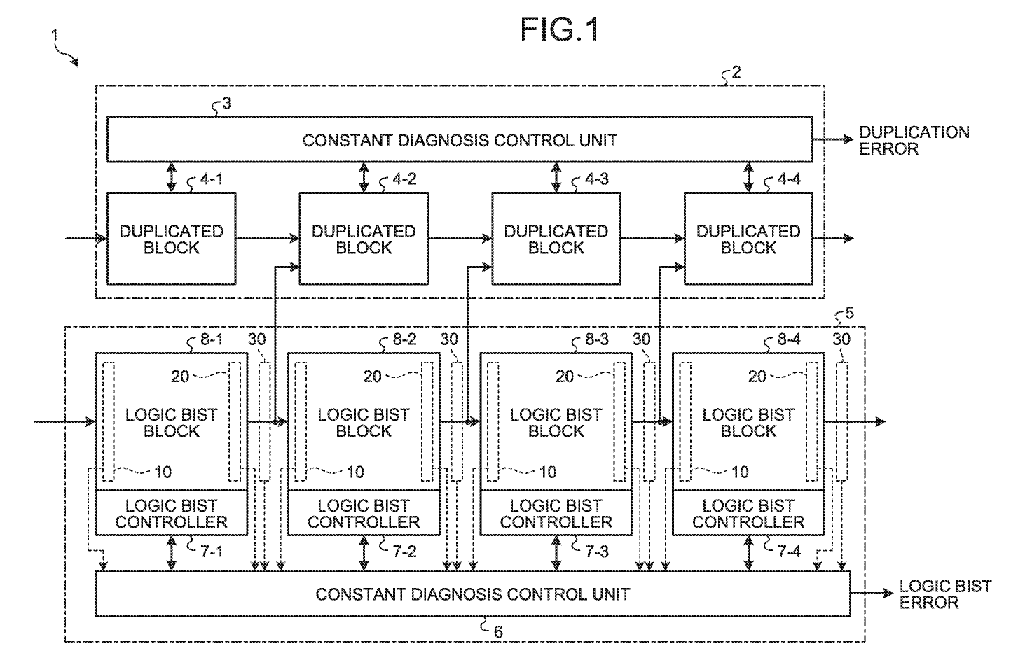

A semiconductor device according to an embodiment is applied to a system of which high reliability is required (e.g., a system of vehicle-mounted products, medical equipment, or the like) and is configured, for example, as shown in FIG. 1. FIG. 1 is a diagram illustrating the configuration of the semiconductor device 1.

In the semiconductor device 1, a logic circuit to perform predetermined control in the system can be incorporated. Even the logic circuit which was determined to be good in the test process before the shipment of the semiconductor device 1 may degrade over years or be subjected to soft errors so as to fail after the shipment. In order to meet the high reliability requirement of the system, two types of mechanisms for diagnosing by itself later-occurring failures that may occur in the logic circuit can be implemented in the semiconductor device 1.

In a first mechanism, the logic circuit is duplicated, and one (a master-side logic circuit) of the two logic circuits is used for predetermined control, and the other (a sub-side logic circuit) is allowed to operate in the same way as the one logic circuit while a controller or the like monitors whether they are operating appropriately so as to perform failure diagnosis for the logic circuit. In a second mechanism, a logic circuit and a built-in self test (BIST) circuit to test the logic circuit are incorporated in the semiconductor device. And during the period when the logic circuit is not operating, the BIST circuit tests the logic circuit to perform failure diagnosis. The test of the logic circuit by the BIST circuit is called a logic BIST.

The duplication is higher in diagnosis reliability, but since the circuit size doubles, the cost may increase in view of the mounting area. For example, in the semiconductor device 1, for a logic circuit such as a CPU, with which there is substantially no idle period resulting in failure diagnosis continuous in time being required, a circuit area 2 for duplication is provided. Further, circuit overhead due to the logic BIST is very small compared with the duplication, and thus the logic BIST is advantageous in terms of cost, but is not as good as the duplication in view of diagnosis coverage. Further, at the time of logic BIST diagnosis, the subject circuit cannot operate for the system. For example, in the semiconductor device 1, for a logic circuit with which there are idle periods (e.g., blanking periods of image processing) during which the logic circuit performs predetermined control processing (e.g., image processing) in response to a request under the control of the CPU, a circuit area 5 for the logic BIST is provided.

The circuit area 2 has multiple duplicated blocks 4-1 to 4-4 and a constant diagnosis control unit 3. Each duplicated block 4-1 to 4-4 includes a master-side logic circuit and a sub-side logic circuit corresponding to the master-side logic circuit. While the master-side logic circuits are operating, the constant diagnosis control unit 3 compares the master-side output and slave-side (sub-side) output of each duplicated block 4-1 to 4-4 and, if there is a difference between the master-side output and the slave-side output, determines that there is a failure. When determining that there is a failure, the constant diagnosis control unit 3 notifies a duplication error to the outside (the controller of the system). That is, the constant diagnosis control unit 3 can achieve the failure diagnosis for the sub-side logic circuit simultaneously while the system (master-side logic circuit) is operating.

The circuit area 5 has multiple logic BIST blocks 8-1 to 8-4, multiple logic BIST controllers 7-1 to 7-4, and a constant diagnosis control unit 6. The multiple logic BIST controllers 7-1 to 7-4 correspond to the multiple logic BIST blocks 8-1 to 8-4. Each logic BIST controller 7 controls the logic BIST in the corresponding logic BIST block 8 under the control of the constant diagnosis control unit 6.

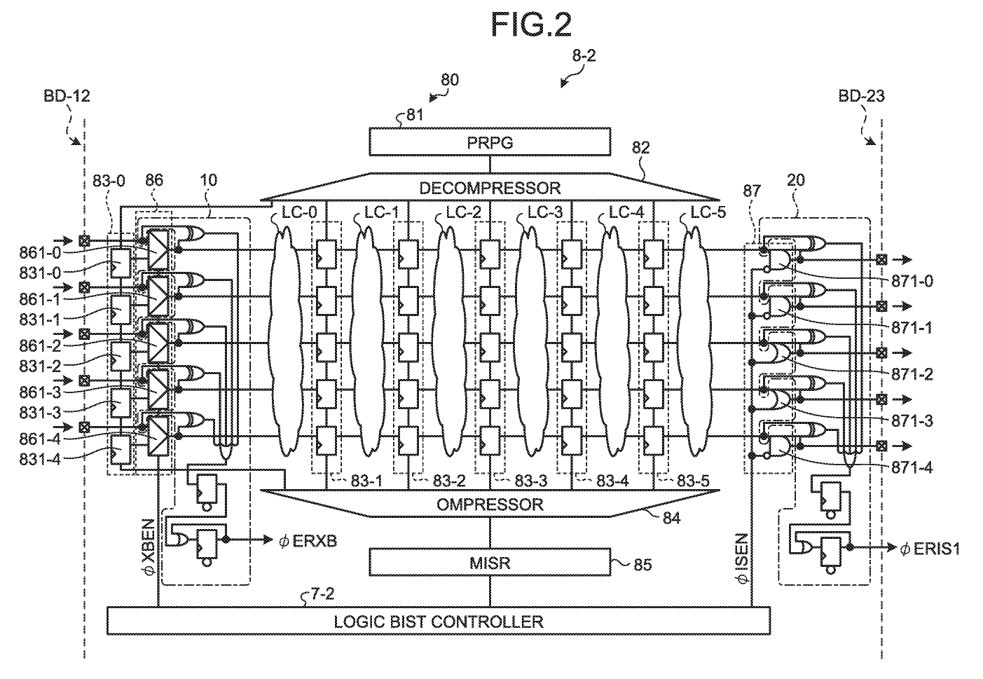

For example, the logic BIST block 8-2 is configured as shown in FIG. 2. FIG. 2 is a diagram illustrating the configuration of the logic BIST block 8. Although FIG. 2 illustrates the configuration of the logic BIST block 8-2, the configurations of the other logic BIST blocks 8-1, 8-3, 8-4 are the same as that of the logic BIST block 8-2.

The logic BIST block 8-2 includes multiple logic circuits LC-0 to LC-5 and a BIST circuit 80. The BIST circuit 80 is connected to the multiple logic circuits LC-0 to LC-5 and performs the logic BIST for each logic circuit LC-0 to LC-5 according to the control by the logic BIST controller 7.

The BIST circuit 80 includes a pseudo-random pattern generator (PRPG) 81, a decompressor 82, multiple scan paths 83-0 to 83-5, a compressor 84, and a test result compression register (MISR: Multiple input signature register) 85. The multiple scan paths 83-0 to 83-5 correspond to the multiple logic circuits LC-0 to LC-5. The BIST circuit 80 causes the PRPG 81 to generate known random data and the decompressor 82 to decompress the data into scan test data to be shifted into the scan paths 83-0 to 83-5 and to be respectively supplied to the corresponding logic circuits LC-0 to LC-5. The BIST circuit 80 has the scan paths 83-0 to 83-5 capture return values (scan results) from the corresponding logic circuits LC-0 to LC-5 and causes the compressor 84 to compress the captured values in the scan paths 83-0 to 83-5 to be sequentially accumulated in the MISR 85. After a scan test is executed with a predetermined number of scan patterns, the logic BIST controller 7 compares the value accumulated in the MISR 85 with an expected value and, if they coincide, determines that there is no failure and, if they do not coincide, determines that there is a failure to notify the diagnosis result to the constant diagnosis control unit 6. If there is a failure according to the notified diagnosis result, the constant diagnosis control unit 6 notifies a logic BIST error to the outside (the controller of the system).

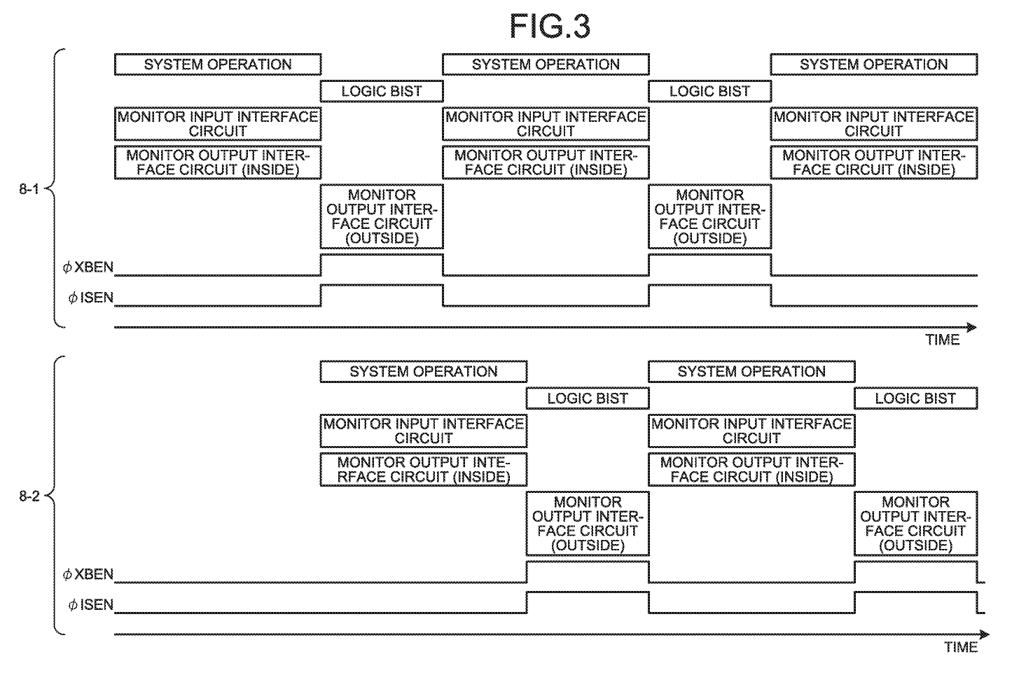

In a system of which high reliability is required (e.g., a system of vehicle-mounted products, medical equipment, or the like), the execution of self-diagnosis can be requested after the startup as well as before system startup (so-called constant diagnosis). Hence, the constant diagnosis control unit 6 controls to execute constant diagnosis for blocks in which the system is not in operation in a time-divisional manner as shown in FIG. 3. For example, FIG. 3 illustrates the case where the logic BIST block 8-2 is performing system operation during the period when the logic BIST block 8-1 is performing the logic BIST and where the logic BIST block 8-1 is performing system operation during the period when the logic BIST block 8-2 is performing the logic BIST.

As to the input signals of the logic BIST block 8, it is desired that an indefinite value (X) not propagate to the MISR 85 while performing the logic BIST of its own. Hence, an input interface circuit 86 can be provided on the input side of the logic BIST block 8 as shown in FIG. 2. The input interface circuit 86 includes multiple selectors 861-0 to 861-4. The multiple selectors 861-0 to 861-4 correspond to multiple dummy flip-flops 831-0 to 831-4 contained in the scan path 83-0. Each selector 861-0 to 861-4 has a first input node connected to the outside (the logic BIST block 8-1) and a second input node connected to the dummy flip-flop 831. When receiving a control signal ϕXBEN of a non-active level (e.g., a low (L) level), each selector 861-0 to 861-4 selects the input signal from the outside (the logic BIST block 8-1) and, when receiving the control signal ϕXBEN of an active level (e.g., a high (H) level), selects the input signal from the dummy flip-flop 831-0 to 831-4.

That is, in the execution of the logic BIST, the input interface circuit 86, receiving the control signal ϕXBEN of the active level (e.g., the H level), performs X-bound processing to select the input signals from the dummy flip-flops 831-0 to 831-4 instead of the input signals from the outside (the logic BIST block 8-1). The dummy flip-flops 831-0 to 831-4 can be controlled by the BIST circuit 80, and by replacing the input signals with known data, an indefinite value (X) is stopped from propagating to the MISR 85. The input interface circuit 86 is also called an X-bound circuit.

Further, it is desired that the logic BIST block 8 not output active logical values as its output signals to another logic BIST block 8 in system operation. Hence, an output interface circuit 87 can be provided on the output side of the logic BIST block 8 as shown in FIG. 2. The output interface circuit 87 includes AND gates 871-0, 871-1, OR gates 872-2, 872-3, and an AND gate 871-4. The AND gates 871-0, 871-1, 871-4 each have a first input node located on the output side of the BIST circuit 80 to be connected to the logic circuit LC-5, a second input node for receiving the logical inverse of a control signal ϕISEN, and an output node connected to another logic BIST block 8. The OR gates 872-2, 872-3 each have a first input node located on the output side of the BIST circuit 80 to be connected to the logic circuit LC-5, a second input node for receiving the control signal ϕISEN, and an output node connected to the other logic BIST block 8. When receiving the control signal ϕISEN of the active level (e.g., the H level), the AND gates 871-0, 871-1, 871-4 fix their outputs at the L level and, when receiving the control signal ϕISEN of the non-active level (e.g., the L level), transfer signals from the logic circuit LC-5 to the other logic BIST block 8 side. When receiving the control signal ϕISEN of the active level (e.g., the H level), the OR gates 872-2, 872-3 fix their outputs at the H level and, when receiving the control signal ϕISEN of the non-active level (e.g., the L level), transfer signals from the logic circuit LC-5 to the other logic BIST block 8 side.

That is, in the execution of the logic BIST, the output interface circuit 87, receiving the control signal ϕISEN of the active level (e.g., the H level), performs isolation processing to fix its output signals at logical values which are taken on at reset. The output interface circuit 87 is also called an isolation cell circuit.

In this case, if a failure is in the input interface circuit 86, the input signals may not propagate correctly when in system operation, and an indefinite value (X) from another logic BIST block 8 adjacent on the input side may propagate to the MISR 85. If an indefinite value (X) propagates to the MISR 85, then the compressed value (MISR result) in the MISR 85 does not hold as an expected value. Thus, the reliability of the test result of the logic BIST may decrease, so that it is difficult to appropriately determine whether the logic circuit LC is good or not.

If a failure is in the output interface circuit 87, the output signals may not propagate correctly to another duplicated block 4 or another logic BIST block 8 adjacent on the output side when in system operation. Or in the logic BIST diagnosis, active logical values may propagate to the other logic BIST block 8 in system operation. This may cause the duplicated block 4 or the logic BIST block 8 in system operation to malfunction, so that it is difficult for the system to operate appropriately.

Accordingly, in the embodiment, by providing a failure monitoring circuit 10 connected to the input interface circuit 86 and a failure monitoring circuit 20 connected to the output interface circuit 87 in the logic BIST block 8 of the semiconductor device 1, failure diagnosis for the input interface circuit 86 and the output interface circuit 87 is made possible.

Specifically, when in system operation, unless having failed, each selector 861-0 to 861-4 of the input interface circuit 86, receiving the control signal ϕXBEN of the non-active level, shall transfer the input signal from the logic BIST block 8 at the preceding stage to the input side of the BIST circuit 80. Hence, when in system operation, the failure monitoring circuit 10 shown in FIG. 2 monitors to confirm that the first input node and output node of each selector 861-0 to 861-4 coincide in signal logical value. The first input node is connected to the logic BIST block 8 at the preceding stage.

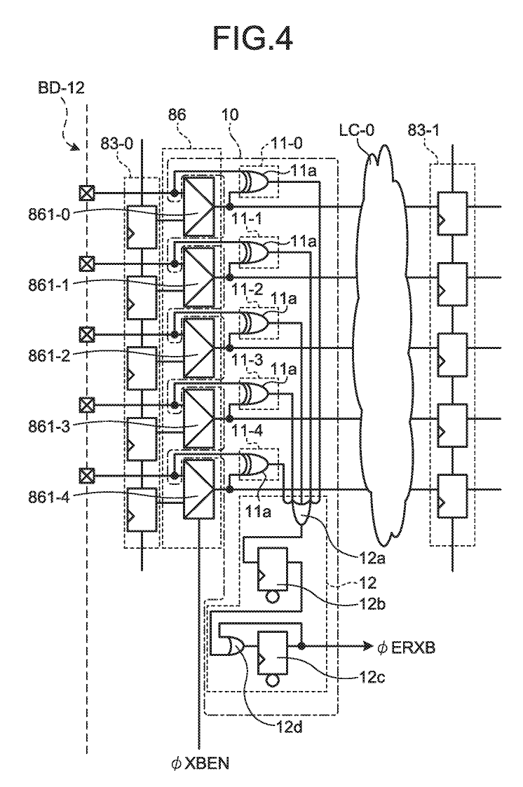

The failure monitoring circuit 10 is configured, for example, as shown in FIG. 4. FIG. 4 is a diagram illustrating the configuration of the input interface circuit 86 and the failure monitoring circuit 10. The failure monitoring circuit 10 includes multiple comparison circuits 11-0 to 11-4 and a failure signal generating circuit 12.

The multiple comparison circuits 11-0 to 11-4 correspond to the multiple selectors 861-0 to 861-4. Each comparison circuit 11-0 to 11-4 is connected to the first input node and output node of the corresponding selector 861. For example, each comparison circuit 11-0 to 11-4 includes an EXOR gate 11a having a first input node connected to the first input node of the selector 861 and a second input node connected to the output node of the selector 861.

The failure signal generating circuit 12 is connected to the multiple comparison circuits 11-0 to 11-4. For example, the failure signal generating circuit 12 includes an OR gate 12a, a flip-flop 12b, a flip-flop 12c, and an OR gate 12d. The OR gate 12a has its input side connected to the multiple comparison circuits 11-0 to 11-4 (multiple EXOR gates 11a) and its output side connected to the flip-flop 12b. The flip-flop 12b has its data input terminal connected to the output side of the OR gate 12a and its output terminal connected to the input side of the OR gate 12d. The OR gate 12d is placed between the flip-flops 12b and 12c. The OR gate 12d has its input side connected to the output terminal of the flip-flop 12b and to the output terminal of the flip-flop 12c.

Each comparison circuit 11-0 to 11-4 compares the logical value of the signal emerging at the first input node of the corresponding selector 861 and the logical value of the signal emerging at the output node thereof to output the comparing result to the failure signal generating circuit 12. That is, if the logical value of the signal emerging at the first input node of the selector 861 and the logical value of the signal emerging at the output node of the selector 861 coincide, then the EXOR gate 11a outputs the comparing result of the L level to the failure signal generating circuit 12. If the logical value of the signal emerging at the first input node of the selector 861 and the logical value of the signal emerging at the output node of the selector 861 do not coincide, then the EXOR gate 11a outputs the comparing result of the H level to the failure signal generating circuit 12. The failure signal generating circuit 12 generates a failure signal ϕERXB according to the comparing results received from the comparison circuits 11-0 to 11-4, which signal indicates the presence or absence of a failure in the input interface circuit 86, and outputs to the outside (e.g., the controller of the system).

That is, while all the outputs of the multiple EXOR gates 11a are at the L level, the OR gate 12a outputs the L level. At this time, the flip-flop 12b samples and holds the L level at a predetermined clock timing to output to the OR gate 12d. Thus, the flip-flop 12c sets the failure signal ϕERXB at the L level (no failure) to output to the outside.

In contrast, when at least one of the outputs of the multiple EXOR gates 11a is at the H level, the OR gate 12a outputs the H level. When receiving the H level, the flip-flop 12b samples and holds the H level at a predetermined clock timing to output to the OR gate 12d. Thus, the flip-flop 12c sets the failure signal ϕERXB at the H level (a failure exists) to output to the outside. If the flip-flop 12b outputs the H level even once, the flip-flop 12c sets the failure signal ϕERXB at the H level (a failure exists) to continue outputting to the outside until being reset.

Thus, if a failure occurs in at least one of the multiple selectors 861-0 to 861-4 of the input interface circuit 86 even temporarily, the failure signal ϕERXB of the H level (a failure exists) is continuously outputted to the outside, so that the occurrence of a failure can be reliably notified to the outside.

In the execution of the logic BIST, for example, the flip-flops 12b, 12c may be reset, and clock supply to the flip-flops 12b, 12c may be stopped in order for the failure monitoring circuit 10 not to operate. Or, in the execution of the logic BIST, the outside may ignore or discard the failure signal ϕERXB supplied from the failure monitoring circuit 10.

Further, when in system operation, unless having failed, the AND gates 871-0, 871-1, OR gates 872-2, 872-3, and AND gate 871-4 of the output interface circuit 87, receiving the control signal ϕISEN of the non-active level, shall transfer the output signals from the output side of the BIST circuit 80 to the outside (another logic BIST block 8 side). Hence, when in system operation, the failure monitoring circuit 20 shown in FIG. 2 monitors to confirm that the first input node and output node of each of the AND gates 871-0, 871-1, 871-4 or OR gates 872-2, 872-3 coincide in signal logical value. The first input node is connected to the output side of the BIST circuit 80.

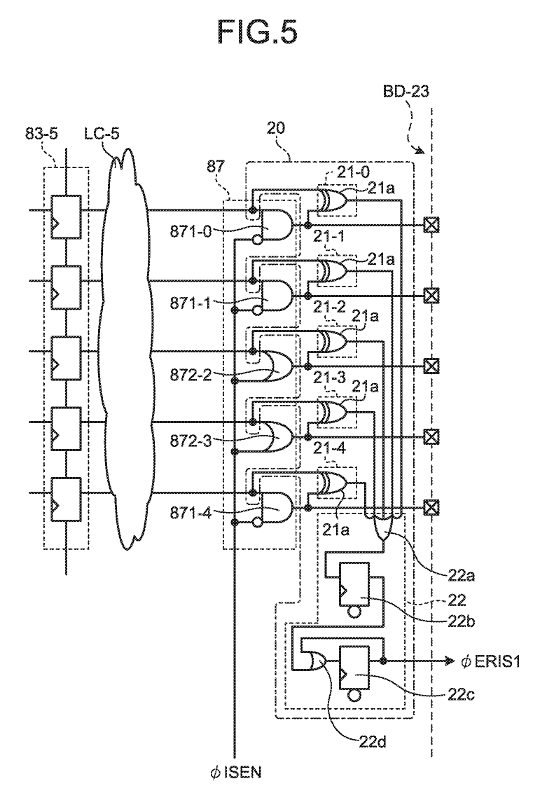

The failure monitoring circuit 20 is configured, for example, as shown in FIG. 5. FIG. 5 is a diagram illustrating the configuration of the output interface circuit 87 and the failure monitoring circuit 20. The failure monitoring circuit 20 includes multiple comparison circuits 21-0 to 21-4 and a failure signal generating circuit 22.

The multiple comparison circuits 21-0 to 21-4 correspond to the AND gates 871-0, 871-1, OR gates 872-2, 872-3, and AND gate 871-4. Each comparison circuit 21-0 to 21-4 is connected to the first input node and output node of the corresponding AND gate 871 or OR gate 872. For example, each comparison circuit 21-0 to 21-4 includes an EXOR gate 21a having a first input node connected to the first input node of the AND gate 871 or OR gate 872 and a second input node connected to the output node of the AND gate 871 or OR gate 872.

The failure signal generating circuit 22 is connected to the multiple comparison circuits 21-0 to 21-4. For example, the failure signal generating circuit 22 includes an OR gate 22a, a flip-flop 22b, a flip-flop 22c, and an OR gate 22d. The OR gate 22a has its input side connected to the multiple comparison circuits 21-0 to 21-4 (multiple EXOR gates 21a) and its output side connected to the flip-flop 22b. The flip-flop 22b has its data input terminal connected to the output side of the OR gate 22a and its output terminal connected to the input side of the OR gate 22d. The OR gate 22d is placed between the flip-flops 22b and 22c. The OR gate 22d has its input side connected to the output terminal of the flip-flop 22b and to the output terminal of the flip-flop 22c.

Each comparison circuit 21-0 to 21-4 compares the logical value of the signal emerging at the first input node of the corresponding AND gate 871 or OR gate 872 and the logical value (expected value) of the signal emerging at the output node thereof to output the comparing result to the failure signal generating circuit 22. That is, if the logical value of the signal emerging at the first input node of the AND gate 871 or OR gate 872 and the logical value (expected value) of the signal emerging at the output node of the AND gate 871 or OR gate 872 coincide, then the EXOR gate 21a outputs the comparing result of the L level to the failure signal generating circuit 22. If the logical value of the signal emerging at the first input node of the AND gate 871 or OR gate 872 and the logical value (expected value) of the signal emerging at the output node of the AND gate 871 or OR gate 872 do not coincide, then the EXOR gate 21a outputs the comparing result of the H level to the failure signal generating circuit 22. The failure signal generating circuit 22 generates a failure signal ϕERIS1 according to the comparing results received from the comparison circuits 21-0 to 21-4, which signal indicates the presence or absence of a failure in the output interface circuit 87, and outputs to the outside (e.g., the controller of the system).

That is, while all the outputs of the multiple EXOR gates 21a are at the L level, the OR gate 22a outputs the L level. At this time, the flip-flop 22b samples and holds the L level at a predetermined clock timing to output to the OR gate 22d. Thus, the flip-flop 22c sets the failure signal ϕERIS1 at the L level (no failure) to output to the outside.

In contrast, when at least one of the outputs of the multiple EXOR gates 21a is at the H level, the OR gate 22a outputs the H level. When receiving the H level, the flip-flop 22b samples and holds the H level at a predetermined clock timing to output to the OR gate 22d. Thus, the flip-flop 22c sets the failure signal ϕERIS1 at the H level (a failure exists) to output to the outside. If the flip-flop 22b outputs the H level even once, the flip-flop 22c sets the failure signal ϕERIS1 at the H level (a failure exists) to continue outputting to the outside until being reset.

Thus, if a failure occurs in at least one of the AND gates 871-0, 871-1, OR gates 872-2, 872-3, and AND gate 871-4 of the output interface circuit 87 even temporarily, the failure signal #ERIS1 of the H level (a failure exists) is continuously outputted to the outside, so that the occurrence of a failure can be reliably notified to the outside.

In the execution of the logic BIST, for example, the flip-flops 22b, 22c may be reset, and clock supply to the flip-flops 22b, 22c may be stopped in order for the failure monitoring circuit 20 not to operate. Or, in the execution of the logic BIST, the outside may ignore or discard the failure signal ϕERIS1 supplied from the failure monitoring circuit 20.

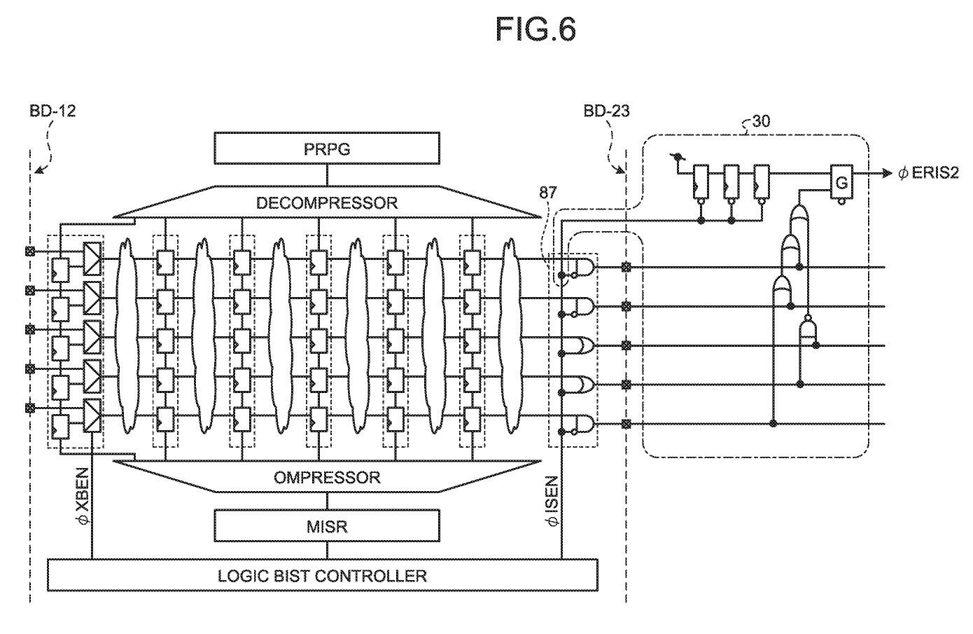

Further, in the execution of the logic BIST, unless having failed, the AND gates 871-0, 871-1, OR gates 872-2, 872-3, and AND gate 871-4 of the output interface circuit 87, receiving the control signal ϕISEN of the active level, shall fix their output signals at logical values which are taken on at reset. Hence, the failure monitoring circuit 30 monitors to confirm that the logical values of the output signals coincide with the logical values (expected values) which are taken on at reset. The failure monitoring circuit 30 is placed mainly outside a boundary BD-23 (that is, between the output interface circuit 87 and the logic BIST block 8 at the subsequent stage) as shown in FIG. 6. FIG. 6 is a diagram illustrating the configuration located between logic BIST blocks 8 (see FIG. 1). In FIG. 6, the failure monitoring circuits 10, 20 are omitted from illustration for simplicity of illustration.

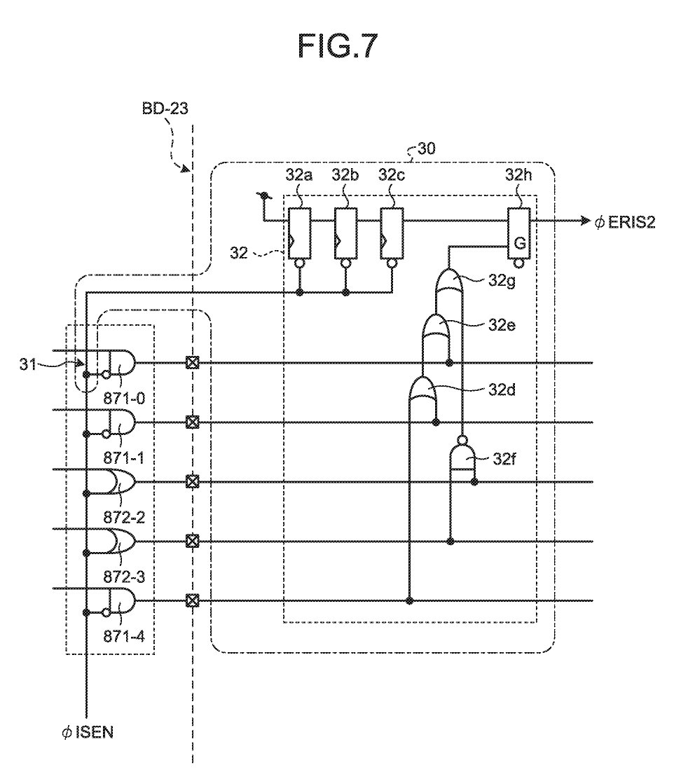

The failure monitoring circuit 30 is configured, for example, as shown in FIG. 7. FIG. 7 is a diagram illustrating the configuration of the output interface circuit 87 and the failure monitoring circuit 30. The failure monitoring circuit 30 includes a failure signal generating circuit 32. The failure signal generating circuit 32 is connected to a supply node 31 for the control signal ϕISEN and to the respective output nodes of the AND gates 871-0, 871-1, OR gates 872-2, 872-3, and AND gate 871-4.

The failure signal generating circuit 32 includes multiple flip-flops 32a, 32b, 32c, OR gates 32d, 32e, a NAND gate 32f, an OR gate 32g, and a latch circuit 32h. The multiple flip-flops 32a, 32b, 32c are connected in series; the data input terminal of the flip-flop 32a at the first stage is fixed at the H level; and the output terminal of the flip-flop 32c at the last stage is connected to the data input terminal of the latch circuit 32h. Each flip-flop 32a, 32b, 32c has its reset terminal connected to the supply node 31 for the control signal ϕISEN. The OR gates 32d, 32e correspond to the AND gates 871-0, 871-1, 871-4 of the output interface circuit 87. The OR gate 32d has its input side connected to the output node of the AND gate 871-1 and to the output node of the AND gate 871-4 and its output side connected to the OR gate 32e. The OR gate 32e has its input side connected to the output node of the AND gate 871-0 and to the output node of the OR gate 32d and its output side connected to the OR gate 32g. The NAND gate 32f corresponds to the OR gates 872-2, 872-3 of the output interface circuit 87. The NAND gate 32f has its input side connected to the output node of the OR gate 872-2 and to the output node of the OR gate 872-3 and its output side connected to the OR gate 32g. The OR gate 32g has its input side connected to the output node of the OR gate 32e and to the output node of the OR gate 32f and its output side connected to the clock terminal G of the latch circuit 32h.

In the execution of the logic BIST, the failure signal generating circuit 32 monitors the output signals of the output interface circuit 87, generates a failure signal ϕERIS2 according to the monitoring result, which signal indicates the presence or absence of a failure in the output interface circuit 87, and outputs to the outside (e.g., the controller of the system).

That is, when a timing comes at which the logic BIST is started causing the control signal ϕISEN to become the active level (e.g., the H level), the flip-flop 32a at the first stage from among the multiple flip-flops 32a to 32c samples and holds the H level at a predetermined clock timing to output to the flip-flop 32b at the next stage. The flip-flop 32b at the next stage samples and holds the H level at the next clock timing to output to the flip-flop 32c at the last stage. The flip-flop 32c at the last stage samples and holds the H level at the yet next clock timing to output to the latch circuit 32h.

At this time, the OR gates 32d, 32e and the NAND gate 32f each output the L level while the logical values of the signals emerging at the output nodes of the corresponding AND gates 871 or OR gates 872 both coincide with the logical value which is taken on at reset. At this time, the OR gate 32g outputs the L level to the clock terminal G of the latch circuit 32h. Thus, the latch circuit 32h holds and outputs the initial state (state of the L level). That is, the latch circuit 32h sets the failure signal ϕERIS2 at the L level (no failure) to output to the outside.

In contrast, the OR gates 32d, 32e and the NAND gate 32f each output the H level when at least one of the logical values of the signals emerging at the output nodes of the corresponding AND gates 871 or OR gates 872 does not coincide with the logical value (expected value) which is taken on at reset. When receiving the H level, the OR gate 32g outputs the H level to the clock terminal G of the latch circuit 32h. Thus, the latch circuit 32h holds and outputs the H level. That is, the latch circuit 32h sets the failure signal ϕERIS2 at the H level (a failure exists) to output to the outside. If the OR gate 32g outputs the H level even once, the latch circuit 32h sets the failure signal ϕERIS2 at the H level (a failure exists) to continue outputting to the outside until being reset.

Thus, if a failure occurs in at least one of the AND gates 871-0, 871-1, OR gates 872-2, 872-3, and AND gate 871-4 of the output interface circuit 87 even temporarily, the failure signal ϕERIS2 of the H level (a failure exists) is continuously outputted to the outside, so that the occurrence of a failure can be reliably notified to the outside.

When in system operation, for example, the latch circuit 32h may be reset in order for the failure monitoring circuit 30 not to operate. Or, when in system operation, the outside may ignore or discard the failure signal ϕERIS2 supplied from the failure monitoring circuit 30.

As such, in the embodiment, in the semiconductor device 1, the failure monitoring circuit 10 connected to the input interface circuit 86 of the logic BIST blocks 8 and the failure monitoring circuits 20, 30 connected to the output interface circuit 87 are provided. Thus, failure diagnosis for the input interface circuit 86 and the output interface circuit 87 in the logic BIST blocks 8 can be executed. Therefore, the results of failure diagnosis for the input interface circuit 86 and the output interface circuit 87 can be notified to the controller or the like of the system, so that the malfunction of the system due to a failure in the input interface circuit 86 and/or the output interface circuit 87 can be prevented. That is, in the semiconductor device 1, failure diagnosis can be appropriately executed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first block; and
a second block adjacent to the first block;
wherein the first block includes:
a logic circuit;
a built-in self test (BIST) circuit connected to the logic circuit;
an interface circuit placed between the second block and the BIST circuit; and
a failure monitoring circuit connected to the interface circuit.

2. The semiconductor device according to claim 1, wherein
the second block is adjacent to an input side of the first block, and the interface circuit is an input interface circuit.

3. The semiconductor device according to claim 2, wherein
the input interface circuit includes:
a first selector having a first input node connected to the second block, a second input node connected to a first dummy circuit, and an output node; and
a second selector having a first input node connected to the second block, a second input node connected to a second dummy circuit, and an output node, and
wherein the failure monitoring circuit includes:
a first comparison circuit connected to the first input node of the first selector and to the output node of the first selector;
a second comparison circuit connected to the first input node of the second selector and to the output node of the second selector; and
a failure signal generating circuit connected to the first comparison circuit and to the second comparison circuit.

4. The semiconductor device according to claim 3, wherein
the failure signal generating circuit includes:
a first OR circuit connected to the first comparison circuit and to the second comparison circuit;
a first flip-flop connected to the first OR circuit;
a second flip-flop; and
a second OR circuit placed between the first flip-flop and the second flip-flop and having its input side connected to an output terminal of the first flip-flop and to an output terminal of the second flip-flop and having its output side connected to an input node of the second flip-flop.

5. The semiconductor device according to claim 4, wherein
the first comparison circuit includes a first exclusive OR circuit having its input side connected to the first input node of the first selector and to the output node of the first selector and having its output side connected to the first OR circuit, and
wherein the second comparison circuit includes a second exclusive OR circuit having its input side connected to the first input node of the second selector and to the output node of the second selector and having its output side connected to the first OR circuit.

6. The semiconductor device according to claim 2, wherein
the failure monitoring circuit operates during a period when test operation by the BIST circuit is not performed and does not operate during a period when test operation by the BIST circuit is performed.

7. The semiconductor device according to claim 4, wherein
during a period when test operation by the BIST circuit is performed, the first flip-flop and the second flip-flop are reset, and clock supply to the first flip-flop and the second flip-flop is stopped.

8. The semiconductor device according to claim 1, wherein
the second block is adjacent to an output side of the first block, and the interface circuit is an output interface circuit.

9. The semiconductor device according to claim 8, wherein
the output interface circuit includes:
a first OR circuit having a first input node placed on an output side of the BIST circuit, a second input node to receive a first control potential, and an output node connected to the second block; and
an AND circuit having a first input node placed on the output side of the BIST circuit, a second input node to receive a second control potential according to the first control potential, and an output node connected to the second block, and
wherein the failure monitoring circuit includes:
a first comparison circuit connected to the first input node of the first OR circuit and to the output node of the first OR circuit;
a second comparison circuit connected to the first input node of the AND circuit and to the output node of the AND circuit; and
a failure signal generating circuit connected to the first comparison circuit and to the second comparison circuit.

10. The semiconductor device according to claim 9, wherein
the failure signal generating circuit includes:
a second OR circuit connected to the first comparison circuit and to the second comparison circuit;
a first flip-flop connected to the second OR circuit;
a second flip-flop; and
a third OR circuit placed between the first flip-flop and the second flip-flop and having its input side connected to an output node of the first flip-flop and to an output node of the second flip-flop and having its output side connected to an input node of the second flip-flop.

11. The semiconductor device according to claim 10, wherein
the first comparison circuit includes a first exclusive OR circuit having its input side connected to the first input node of the first selector and to the output node of the first selector and having its output side connected to the first OR circuit, and
wherein the second comparison circuit includes a second exclusive OR circuit having its input side connected to the first input node of the second selector and to the output node of the second selector and having its output side connected to the first OR circuit.

12. The semiconductor device according to claim 2, wherein
the failure monitoring circuit operates during a period when test operation by the BIST circuit is not performed and does not operate during a period when test operation by the BIST circuit is performed.

13. The semiconductor device according to claim 10, wherein
during a period when test operation by the BIST circuit is performed, the first flip-flop and the second flip-flop are reset, and clock supply to the first flip-flop and the second flip-flop is stopped.

14. The semiconductor device according to claim 1, wherein
the second block is adjacent to an output side of the first block, and
the interface circuit is an output interface circuit, and
the failure monitoring circuit is placed between the output interface circuit and the second block.

15. The semiconductor device according to claim 14, wherein
the output interface circuit includes:
a first OR circuit having a first input node placed on an output side of the BIST circuit, a second input node connected to a first control potential, and an output node connected to the second block; and
an AND circuit having a first input node placed on the output side of the BIST circuit, a second input node connected to a second control potential according to the first control potential, and an output node connected to the second block, and
wherein the failure monitoring circuit includes a failure signal generating circuit connected to the first control potential, to the output node of the first OR circuit, and to the output node of the AND circuit.

16. The semiconductor device according to claim 15, wherein
the failure signal generating circuit includes:
a flip-flop having a reset terminal connected to the first control potential;
a second OR circuit connected to the output node of the AND circuit;
a negative AND circuit connected to the output node of the first OR circuit;
a third OR circuit connected to the output node of the second OR circuit and to the output node of the negative AND circuit; and
a latch circuit having an input node connected to the output node of the flip-flop and a clock node connected to the output node of the third OR circuit.

17. The semiconductor device according to claim 16, wherein
the failure signal generating circuit includes a plurality of stages of the flip-flops, and
wherein from among the plurality of stages of flip-flops, a first stage of flip-flop has its data input terminal connected to a fixed potential.

18. The semiconductor device according to claim 14, wherein
the failure monitoring circuit operates during a period when test operation by the BIST circuit is performed and does not operate during a period when test operation by the BIST circuit is not performed.

19. A failure diagnosis method for a semiconductor device having a first block and a second block placed on an input side of the first block, comprising:
comparing a signal at an input node of and a signal at the output node of a selector contained in an input interface circuit placed in the first block and between the second block and a built-in self test circuit, the input node being connected to the second block; and
performing failure diagnosis for the input interface circuit according to the comparing result.

20. A failure diagnosis method for a semiconductor device having a first block and a second block placed on an output side of the first block, comprising:
comparing an expected value and a value outputted from a logic circuit contained in an output interface circuit placed in the first block and between the second block and a built-in self test circuit; and
performing failure diagnosis for the output interface circuit according to the comparing result.
